(19) United States
(12) Patent Application Publication
(10) Pub. No.: US 2007/0291533 A1
(43) Pub. Date: Dec. 20, 2007

(54) PHASE CHANGE MEMORY DEVICE AND FABRICATION METHOD THEREOF

(75) Inventors: Yen Chuo, Taipei City (TW); Wen-Han Wang, Hsinchu City (TW); Min-Hung Lee, Taipei County (TW); Hong-Hui Hsu, Changhua County (TW); Chien-Min Lee, Kaohsiung City (TW); Te-Sheng Chao, Taichung County (TW); Yi-Chan Chen, Yunlin County (TW); Wei-Su Chen, Hsinchu (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/758,559

(22) Filed: Jun. 5, 2007

(30) Foreign Application Priority Data
Jun. 16, 2006 (TW) TW95121586

(51) Int. Cl. G11C 11/00

(52) U.S. Cl. 365/163

(57) ABSTRACT

The invention provides a phase change memory device comprising a stacked structure disposed on a substrate. The stacked structure comprises a first electrode, a second electrode overlying the first electrode and an insulating layer interposed between the first and the second electrodes. A memory spacer is formed on part of the sidewall of the stacked structure to contact the first electrode, the insulating layer and the second electrode.

### BACKGROUND OF THE INVENTION

1. Field of the Invention

The invention relates to a memory device and in particular to a phase change memory device and fabrication method thereof.

2. Description of the Related Art

Phase change memory device are non-volatile, highly readable, and programmable with low driving voltage/current. Phase change material applied therein generally has at least two phases: crystalline and amorphous states, each having different electrical characteristics. For example, in amorphous state the material exhibits a higher resistivity than that in crystalline state. Such phase change material may be switched between numerous electrically detectable conditions of varying resistivity in nanoseconds with the input of pico joules of energy.

U.S. Pat. Nos. 6,830,952 and 6,864,503 disclose a spacer phase change memory device. FIG. 1 is a cross-section of spacer phase change memory device 100, comprising a stacked structure 103 and a memory spacer 101. FIG. 2 is a top view of the spacer phase change memory device 100. As shown in FIG. 2, the memory spacer 101 encapsulates the sidewall of the stacked structure 103. To heat the sidewall of the stacked structure 103 uniformly during programming and erasing, the stacked structure is subjected to a higher erase current, causing a higher threshold voltage and power consumption. In addition, owing to that the heat produced for programming and erasing will dissipating in all transverse directions, the space between two adjacent spacer phase change memory devices 100 is hard to shrink. Furthermore, to lower the resistivity of electrodes, the transverse cross-section area of the electrode is increased. Nevertheless, with larger transverse cross-section area of the electrode, the sidewall area of the stacked structure 103 also increases, causing not only an enlarged memory device, but also non-uniformly heating, higher threshold voltage and higher power consumption in programming and erasing.

### BRIEF SUMMARY OF THE INVENTION

The invention provides a phase change memory device and fabricating method thereof with lowered threshold voltage and power consumption, reduced space required, providing increased memory density, and reduced sidewall area.

A phase change memory device comprises a stacked structure disposed on a substrate, the stacked structure comprising a first electrode, an second electrode disposed on the first electrode and an insulating layer interposed between the first electrode and the second electrode, and a memory spacer formed on part of the sidewall of the stacked structure, contacting the first electrode, the insulating layer and the second electrode.

A method of fabricating a phase change memory device comprises forming a stacked stricture on a substrate, the stacked structure comprising a first electrode, an insulating layer on the first electrode, and an second electrode on the insulating layer, depositing a phase change material covering the stacked structure, patterning the phase change material to leave the phase change material to part of the sidewall and a top surface of the stacked structure, and etching back the patterned phase change material, forming a memory spacer on the part of the sidewall of the stacked structure to contact the second electrode, the insulating layer and the first electrode.

A detailed description is given in the following with reference to the accompanying drawing.

### BRIEF DESCRIPTION OF THE DRAWINGS

The invention can be more fully understood by reading the subsequent detailed description and examples with references made to the accompanying drawings, wherein:

FIG. 1 is a cross-section of the traditional spacer phase change memory device;

FIG. 2 is a top view of the traditional spacer phase change memory device;

FIG. 3 to FIG. 7b show process flows of the invention;

### DETAILED DESCRIPTION OF INVENTION

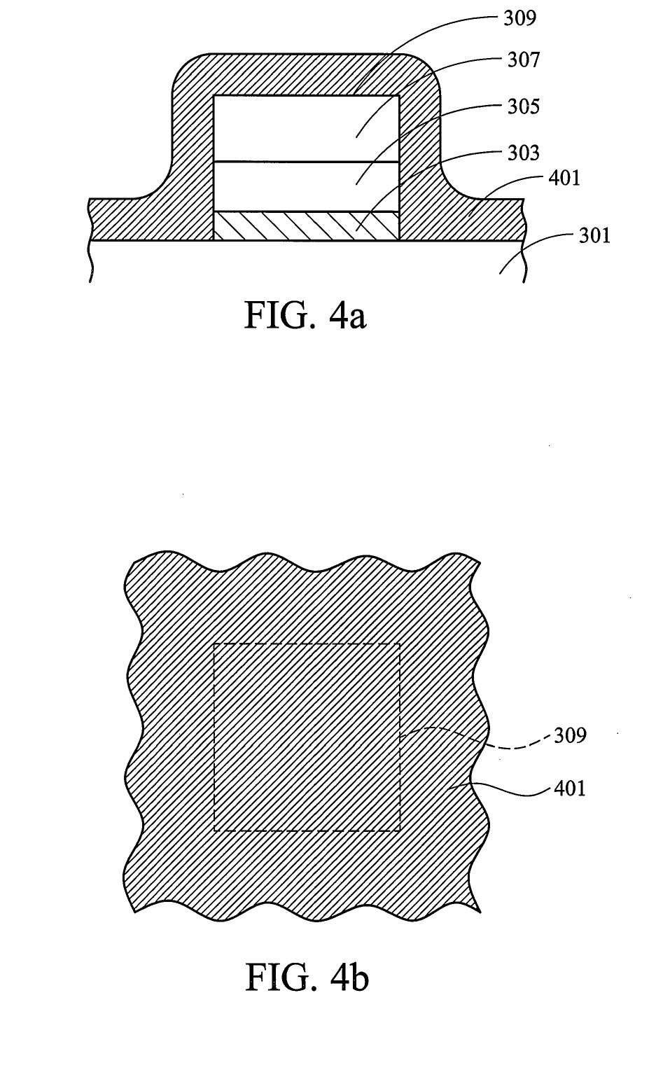

FIG. 3 to FIG. 7b show the process flows of a phase change memory device according to embodiments of the invention.

As shown in FIG. 3, a first conductive layer, an insulating layer and an second conductive layer are formed in sequence on a substrate 301, and then patterned to obtain a stacked structure 309 comprising a first electrode 303, an insulating layer 305, and an second electrode 307, wherein the first electrode 303 serves as a thermal electrode with thickness can be less than the lithography limit, such as between 10 nm and 30 nm. The second electrode 307 may comprise TiN, TaN or TiW, and its thickness is, but is not limited to, about between 200 nm-400 nm beneficial for electrical conduction. In addition, the second electrode 307 may be doped with Ti, W, Mo, Al, Ta, Cu, Pt, Ir, La, Ni or O depending on the performance requirements of the device. The insulating layer 305 is sandwiched in between the second electrode 307 and first electrode 303, and may comprise SiN, SiO₂, Al₂O₃, oxide-nitride-oxide (ONO) multilayer structure or silicon-oxide-nitride-oxide (SONO) multilayer structure. In addition, based on any further device performance requirement, the insulating layer 305 may be doped with Ti, Si, Mo, Al, Ta, Ni or O. The first electrode 303 may comprise metal or half-metal, such as TiAlN, serving as a thermal electrode.

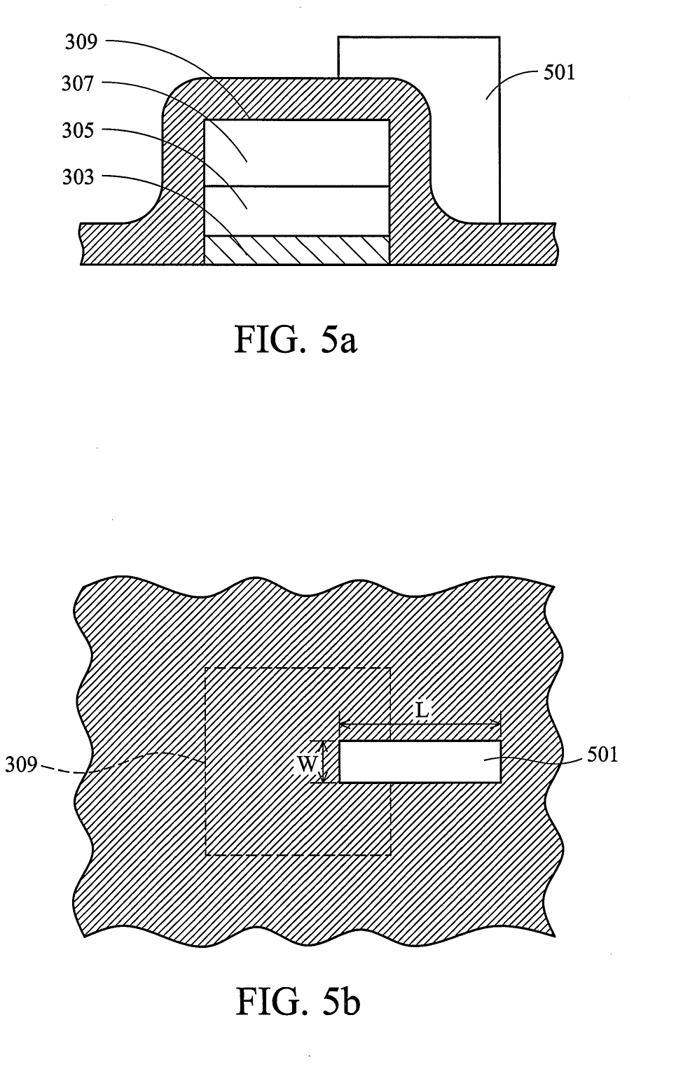

As shown in FIG. 4a, a phase change material 401 is deposited, covering the top surface and sidewall of the stacked structure 309 and part of the substrate 301, by chemical vapor deposition (CVD) or sputtering for example. The phase change material 401 may be chalcogenide, such as ternary Ge—Te—Sb chalcogenide or binary Te—Sb chalcogenide, and may also be doped with Cr, Fe, Ni or combinations thereof. Additionally, Bi, Pb, Sn, As, S, Si, P, O or combinations thereof can also be used as dopant. The phase change material 401 has at least two phases, depending on how it is programmed. FIG. 4b is a top view of FIG. 4a. As shown in FIG. 4b, the phase change material 401 covers the stacked structure 309 entirely. FIG. 5a shows the lithography process forming a photoresist layer on the phase change material 401, and FIG. 5b is a top view thereof. As shown in FIG. 5a, a photoresist layer is formed on the phase change material 401 and then patterned to obtain a photoresist 501 as a mask, covering part of top surface of the stacked structure 309 and part of the phase change material 401 on the sidewall of the stacked structure 309. W in FIG. 5b, the pattern width of the photoresist 501, could be as narrow as lithography limit. L in FIG. 5b, the pattern length of the photoresist 501, could be slightly larger than the lithography limit to tolerate the misalignment between different mask layers, such that the patterned phase change material can connect both the second electrode 307 and the substrate 301.

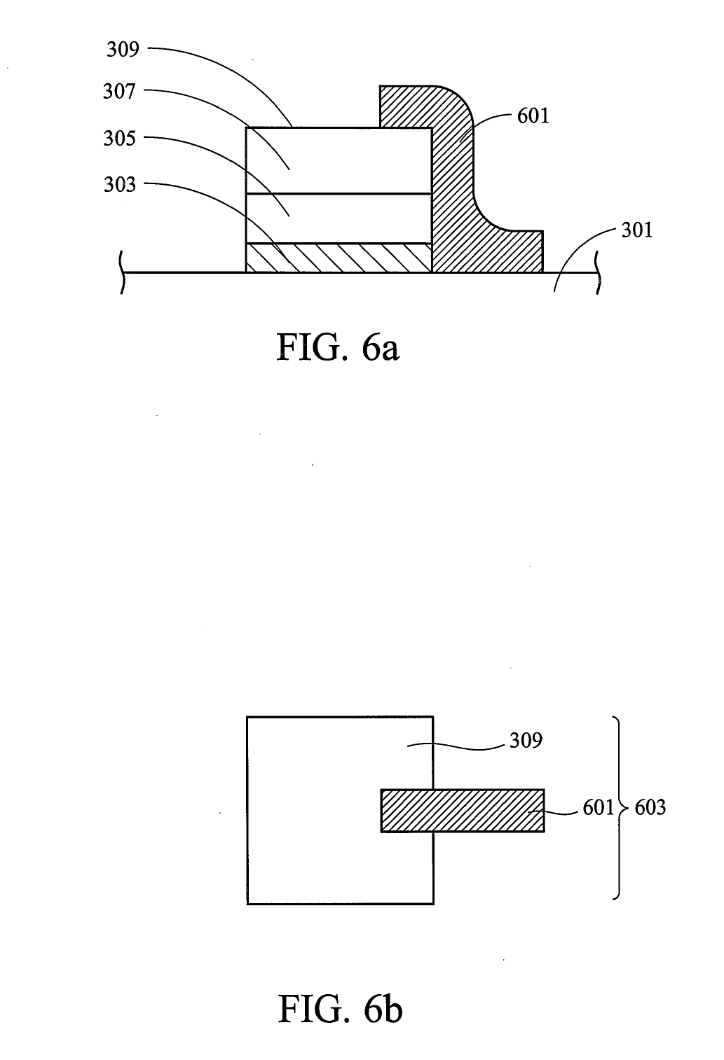

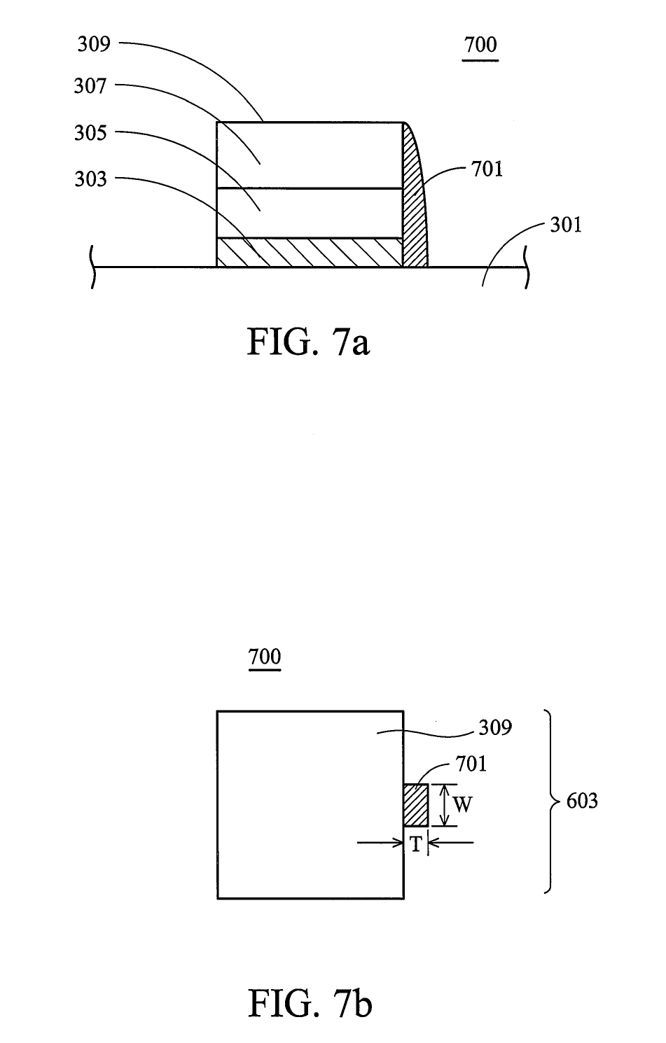

The phase change material is etched using the photoresist 501 as a mask to form a bar-shaped structure 601 covering part of the top surface of the stacked structure 309 and extending to part of the substrate 301 along the sidewall thereof, as shown in FIG. 6a. As shown in FIG. 6a, the etched phase change material remains only to part of the top surface and part of the sidewall of the stacked structure 309, contacting the second electrode 307, the insulating layer 305, first electrode 303 and the substrate 301. FIG. 6b is a top view of FIG. 6a. Even though the phase change material in FIG. 6b is confined to the center part of the spacer region 603 at the right side of the stacked structure 309, it is not limited to, and may be located to the left, top or bottom side or to any corner thereof. An anisotropic etching back is performed to remove the phase change material at the top of the stacked structure 309. Accordingly, part of the phase change material on the substrate 301 is also removed and the remaining phase change material on the sidewall of the stacked structure 309 forms a memory spacer 701, completing a phase change memory device, as shown in FIG. 7a. FIG. 7b shows a top view of FIG. 7a. In FIG. 7b, T, the thickness of the memory spacer 701, may be reduced less than lithography limit by etching. The phase change memory device can be connected to a driving device, such as MOSFET, BJT or diode.

In the fabricating method in the embodiment, the phase change material is confined to be left inside spacer region 603 by conventional lithography and etching, as shown in FIG. 6a and FIG. 6b, and is etched back to form memory spacer 701, as shown in FIG. 7a and FIG. 7b. If the etching back process is performed prior to patterning (including lithography and relevant etching), the thickness of the memory spacer formed by the etching back process may be less than lithography limit, causing alignment difficulty in following lithography defining the location of the memory spacer. According to the embodiment, conventional lithography used to define the width of the phase change material is performed prior to the etching back defining the thickness of the memory spacer, as shown in FIG. 5a to FIG. 6b , such that the thickness of the memory spacer is reduced beyond lithography limit without requiring complicated lithographic alignment.

Unlike conventional phase change memory devices having encapsulating all the sidewall of a stacked structure, the phase change memory device of the disclosed embodiment limits phase change material to part of the sidewall of the stacked structure 309. The location of the phase change memory device of the embodiment depends on the width W and thickness T of the memory spacer 701, where the width W is about lithography limit and the thickness T may be beyond lithography limit by etching back, obtaining a smaller phase change region to reduce programming and erase current/voltage, and the threshold voltage as well. Furthermore, the sidewall area of the second electrode 307 and first electrode 303 is much larger than that of the memory spacer 701, whereby improving the current density.

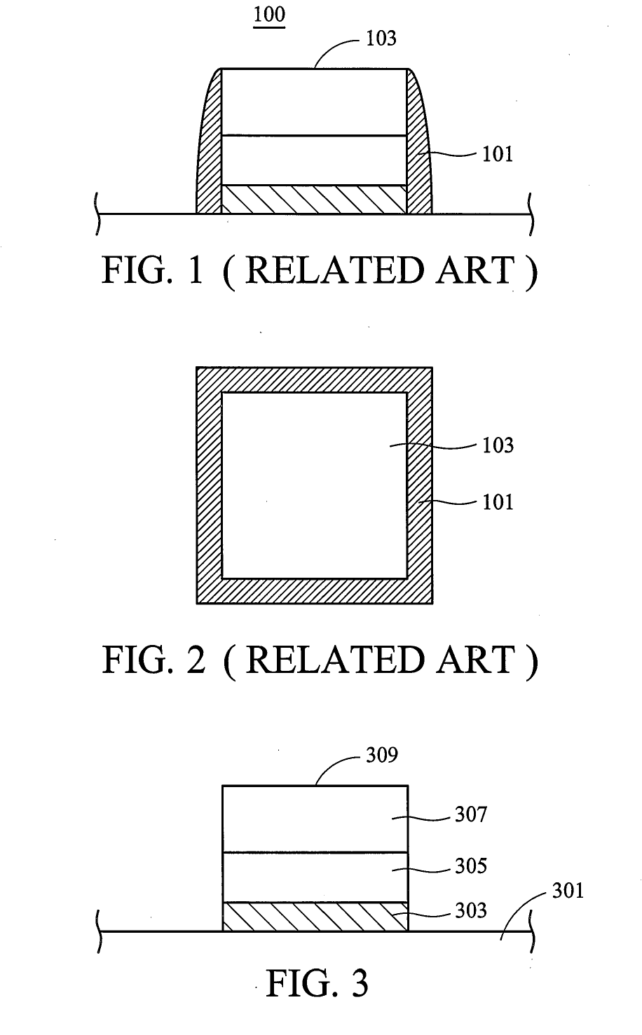

Compared to the conventional phase change memory device, the sidewall area of the memory spacer 701 and that of the second electrode 307 and first electrode 303 are independent. In other words, the sidewall area of the memory spacer 701 need not vary while the sidewall of the second electrode 307 and first electrode 303 changes, such that the top area of the stacked structure 309 can be increased to reduce the resistivity thereof without increasing the sidewall area of the memory spacer 701. Furthermore, according to the conventional phase change memory device shown in FIG. 1 and FIG. 2, the sidewall of the stacked structure is encapsulated by the memory spacer 101, with heat produced thereby during programming and erase diffusing/dissipating in all transverse directions, thus restricting the density of memory. In the phase change memory device in the embodiment, phase change material is only formed and positioned on part of the sidewall of the stacked structure 309 as shown in FIG. 7b, substantially directing heat diffusion and dissipation from the memory spacer, such that the space between each stacked structure 309 can be reduced to increase the memory density.

In view of foregoing, it is readily appreciated that the embodiment of the invention provides the following advantages:
1. The driving current applied to the phase change memory device can be reduced and focused with shrunk volume of phase change material that has a dimension beyond lithography limit.
2. With directed heat diffusion, the memory density can be improved by reducing the space between stacked structures.
3. Free of affecting the volume of the phase change material, the top area of the stacked structure can be increased to improve the conductivity of the electrode.

Finally, while the invention has been described by way of example and in terms of embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A phase change memory device, comprising:
a stacked structure disposed on a substrate, comprising a first electrode, a second electrode disposed on the first electrode and an insulating layer interposed between the first electrode and the second electrode; and
a memory spacer formed on part of the sidewall of the stacked structure, contacting the first electrode, the insulating layer and the second electrode.

2. The phase change memory device as claimed in claim 1, wherein the memory spacer comprises at least two solid phases.

3. The phase change memory device as claimed in claim 1, wherein the memory spacer comprises chalcogenide.

4. The phase change memory device as claimed in claim 3, wherein the chalcogenide comprises ternary Ge—Te—Sb chalcogenide.

5. The phase change memory device as claimed in claim 3, wherein the chalcogenide further is doped with Cr, Fe, Ni or combinations thereof .

6. The phase change memory device as claimed in claim 3, wherein the chalcogenide is doped with Bi, Pb, Sn, As, S, Si, P, O or combinations thereof .

7. The phase change memory device as claimed in claim 1, wherein the second electrode comprises TiN, TaN or TiW.

8. The phase change memory device as claimed in claim 7, wherein the second electrode is doped with Ti, W, Mo, Al, Ta, Cu, Pt, Ir, La, Ni or O.

9. The phase change memory device as claimed in claim 1, wherein the first electrode comprises metal or half-metal serving as a thermal electrode.

10. The phase change memory device as claimed in claim 1, wherein the first electrode comprises TiAlN.

11. The phase change memory device as claimed in claim 1, wherein the insulating layer comprises SiN, SiO₂, Al₂O₃, oxide-nitride-oxide or silicon-oxide-nitride-oxide multilayer structures.

12. The phase change memory device as claimed in claim 11, wherein the insulating layer further comprises dopant of Ti, Si, Mo, Al, Ta, Ni or O.

13. The phase change memory device as claimed in claim 1, wherein the width of the memory spacer is about lithography limit.

14. The phase change memory device as claimed in claim 1, wherein the thickness of the memory spacer is less than lithography limit.

15. The phase change memory device as claimed in claim 1, connecting to a driving device.

16. The phase change memory device as claimed in claim 15, wherein the driving device comprises MOSFET, BJT or diode.

17. A method of fabricating a phase change memory device, comprising:
forming a stacked structure on a substrate, wherein the stacked structure comprises a first electrode, an insulating layer on the first electrode, and an second electrode on the insulating layer;
depositing a phase change material to cover the stacked structure;
patterning the phase change material to leave the phase change material to part of the sidewall and a top surface of the stacked structure; and
etching back the patterned phase change material and forming a memory spacer on the part of the sidewall of the stacked structure to contact the second electrode, the insulating layer and the first electrode.

18. The method of fabricating the phase change memory device as claimed in claim 17, wherein the formation of the stacked structure comprises:
forming a first electrode layer, an insulating layer and an second electrode in sequence; and
patterning the first electrode layer, the insulating layer and the second electrode to form the stacked structure.

19. The method of fabricating the phase change memory device as claimed in claim 17, wherein the patterned phase change material is bar-shaped, covering part of the top surface of the stacked structure and extending to part of the substrate along the sidewall thereof.

20. The method of fabricating the phase change memory device as claimed in claim 19, wherein the length of the bar-shaped phase change material is larger than lithography limit.

21. The method of fabricating the phase change memory device as claimed in claim 17, wherein the first electrode comprises metal,or half metal.

22. The method of fabricating the phase change memory device as claimed in claim 17, wherein the second electrode comprises TiN, TaN or TiW.

23. The method of fabricating the phase change memory device as claimed in claim 17, wherein the second electrode is doped with Ti, W, Mo, Al, Ta, Cu, Pt, Ir, La, Ni or O.

24. The method of fabricating the phase change memory device as claimed in claim 17, wherein the phase change material comprises chalcogenide.

25. The method of fabricating the phase change memory device as claimed in claim 24, wherein the chalcogenide comprises ternary Ge—Te—Sb chalcogenide.

26. The method of fabricating the phase change memory device as claimed in claim 24, wherein the chalcogenide is doped with Cr, Fe, Ni or combinations thereof.

27. The method of fabricating the phase change memory device as claimed in claim 24, wherein the chalcogenide is doped with Bi, Pb, Sn, As, S, Si, P, O or combinations thereof.

28. The method of fabricating the phase change memory device as claimed in claim 17, wherein the insulating layer comprises SiN, SiO₂, Al₂O₃, oxide-nitride-oxide or silicon-oxide-nitride-oxide multilayer structures.

29. The method of fabricating the phase change memory device as claimed in claim 28, wherein the insulating layer is doped with Ti, Si, Mo, Al, Ta, Ni or O.

30. The method of fabricating the phase change memory device as claimed in claim 17, wherein the width of the memory spacer is about lithography limit.

31. The method of fabricating the phase change memory device as claimed in claim 17, wherein the thickness of the memory spacer is less than lithography limit.

32. The method of fabricating the phase change memory device as claimed in claim 17, wherein the phase change material is deposited by chemical vapor deposition or sputtering.

33. The method of fabricating the phase change memory device as claimed in claim 17, wherein the etching is anisotropic.
